(19) United States
(12) Patent Application Publication
(10) Pub. No.: US 2021/0111201 A1
(43) Pub. Date: Apr. 15, 2021

(54) Image Sensor Structure and Method of Forming the Same

(71) Applicant: Silicon Optronics, Inc., Hsinchu (TW)

(72) Inventors: Ming-Xiang LI, Hsinchu (TW); Bo-Ray LEE, Hsinchu (TW); Yu-Yuan YAO, Hsinchu (TW)

(21) Appl. No.: 15/931,972

(22) Filed: May 14, 2020

(30) Foreign Application Priority Data
Oct. 9, 2019 (TW) 108136558

(51) Int. Cl. H01L 27/146

(52) U.S. Cl. CPC H01L 27/1463; H01L 27/14643; H01L 27/14616

(57) ABSTRACT

An image sensor structure including: a substrate, having a first conductive type; a first well region and a second well region disposed in the substrate and spaced apart; an isolation region disposed in the first well region; a gate disposed on the substrate and between the first well region and the second well region; and a pinned photodiode disposed in the substrate and between the first well region and the second well region is provided. The pinned photodiode includes: a first doping region disposed in the substrate and having a first doping concentration and the first conductive type; and a second doping region disposed on the first doping region and having a second doping concentration opposite to the first conductive type. One or both of the first doping region and the second doping region is non-uniform and the first doping concentration is greater than the second doping concentration.

### CROSS REFERENCE TO RELATED APPLICATIONS

This Application claims priority of Taiwan Patent Application No. 108136558, filed on Oct. 9, 2019, the entirety of which is incorporated by reference herein.

### BACKGROUND OF THE INVENTION

### Field of the Invention

The present invention relates to an image sensor structure and a method of forming the same, and it particularly relates to an image sensor structure with a pinned photodiode and a method of forming the same.

### Description of the Related Art

Image sensors have been widely used in various image capturing devices, such as cameras, digital cameras, and the like. The image sensor, such as a charge-coupled device (CCD) image sensing device or a complementary metal-oxide semiconductor (CMOS) image sensing device, has a photosensitive element for converting incident light into electrical signals. The image sensor has a pixel array, and each pixel has a photosensitive element. The image sensor also has logic circuitry for transmitting and processing electrical signals.

Although the existing image sensors can substantially meet their originally intended use, they have not yet fully met requirements in every respect. For example, when a pixel is large, the length of the photodiode also increases. At this time, the potential profile of the photodiode will be too flat, so the photodiode does not have a sufficiently strong electric field to conduct the charge on the edge of the photodiode away from the gate, or it takes a long time to conduct the charge.

Therefore, a novel image sensor is needed to increase charge transfer efficiency.

### BRIEF SUMMARY OF THE INVENTION

An image sensor structure is provided according to some embodiments of the invention. The image sensor structure includes: a substrate, having a first conductive type; a first well region and a second well region disposed in the substrate and spaced apart; an isolation region disposed in the first well region; a gate disposed on the substrate and between the first well region and the second well region; and a pinned photodiode disposed in the substrate and between the first well region and the second well region, wherein the pinned photodiode includes: a first doping region disposed in the substrate and having a first doping concentration and the first conductive type; and a second doping region disposed on the first doping region and having a second doping concentration opposite to the first conductive type, wherein one or both of the first doping region and the second doping region is non-uniform and the first doping concentration is greater than the second doping concentration.

A method of forming an image sensor structure is provided according to some embodiments of the invention. The method includes: providing a substrate having a first conductive type; forming a first well region and a second well region in the substrate, wherein the first well region and the second well region are separated from each other; forming an isolation region in the first well region; forming a gate on the substrate and between the first well region and the second well region; and forming a pinned photodiode in the substrate and between the first well region and the second well region, wherein the pinned photodiode includes: forming a first doped region in the substrate, wherein the first doped region has a first doping concentration and the first conductive type; and

forming a second doped region under the first doped region, wherein the second doped region has a second doping concentration and a second conductive type that is the opposite of the first conductive type, wherein one or both of the first doping concentration and the second doping concentration is non-uniform, and the first doping concentration is greater than the second doping concentration.

### BRIEF DESCRIPTION OF THE DRAWINGS

The embodiments of the present invention will be described in detail below with reference made to the accompanying drawings. It should be noted that, in accordance with standard practice in the industry, the various features are not drawn to scale and are merely illustrative. In fact, the dimensions of the elements may be arbitrarily enlarged or reduced to clearly show the features of the embodiments of the present invention.

FIG. 1 is a cross-sectional view of an image sensor structure 100 illustrated according to some embodiments of the present invention.

FIG. 2 is a cross-sectional view of an image sensor structure 200 illustrated according to some embodiments of the present invention.

FIG. 3 is a cross-sectional view of an image sensor structure 300 illustrated according to some embodiments of the present invention.

FIG. 4 is a cross-sectional view of an image sensor structure 400 illustrated according to some embodiments of the present invention.

### DETAILED DESCRIPTION OF THE INVENTION

The image sensor structure and the method of forming the same according to embodiments of the present invention will be described in detail below. It should be appreciated that, in order to clearly describe the present invention, the following disclosure provides many different embodiments, or examples, for implementing different features of the invention. In addition, similar and/or corresponding reference numerals may be used in different embodiments to indicate similar and/or corresponding elements in order to clearly describe the embodiments of the present invention. However, the use of similar and/or corresponding reference numerals is done for the purpose of simplicity and clarity and does not in itself dictate a relationship between the various embodiments and/or configurations discussed.

In addition, in this specification, relative expressions are used. For example, “lower”, “bottom”, “higher” or “top” are used to describe the position of one element relative to another. It should be appreciated that if a device is flipped upside down, an element that is “lower” will become an element that is “higher”.

It should be understood that although the terms “first”, “second”, “third” etc. may be used herein to describe various elements, components, regions, layers, and/or portions, these elements, components, regions, layers, and/or portions should not be limited by these terms. These terms are only used to distinguish one element, component, region, layer, and/or portion from another element, component, region, layer and/or portion. Thus, a first element, component, region, layer, and/or portion discussed below could be termed a second element, component, region, layer, and/or portion without departing from the teachings of the present invention.

Herein, the terms “about”, “approximately” and “substantially” typically mean +/−20% of the stated value or range, typically +/−10% of the stated value or range, typically +/−5% of the stated value or range, typically +/−3% of the stated value or range, typically +/−2% of the stated value or range, typically +/−1% of the stated value or range, and typically +/−0.5% of the stated value or range. The stated value of the present invention is an approximate value. Namely, the meaning of “about”, “approximately” and “substantially” may be implied if there is no specific description of “about”, “approximately” and “substantially”.

In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed as referring to the orientation as described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Unless defined otherwise, all technical and scientific terms used herein have the same meaning as commonly understood by one of ordinary skill in the art to which this invention belongs. It should be appreciated that, in each case, the term, which is defined in a commonly used dictionary, should be interpreted as having a meaning that conforms to the relative skills of the present invention and the background or the context of the present invention, and should not be interpreted in an idealized or overly formal manner unless so defined.

This description of the exemplary embodiments is intended to be read in connection with the accompanying drawings, which are to be considered part of the entire written description. The drawings are not drawn to scale. The shapes and thicknesses of the embodiments may be exaggerated in the drawings in order to clearly illustrate the features of the embodiments of the present invention. In addition, the structures and devices in the drawings are schematically illustrated in order to clearly illustrate the features of the embodiments of the invention.

Although the steps in some of the described embodiments are performed in a particular order, these steps can also be performed in another logical order. In various embodiments, some of the described steps may be replaced or omitted, and some other operations may be performed before, during, and/or after the steps described in the embodiments of the present invention. The high electron mobility transistor in the embodiments of the invention may incorporate other features. Some features may be replaced or omitted in different embodiments.

The embodiments of the present invention provide an image sensor structure and a method of forming the same. By making one or both of the first doped region and the second doped region of the embedded photodiode have a non-uniform doping concentration, either the doping concentration of the first doped region will decrease in the direction from the isolation region to the gate, or the doping concentration of the second doped region will decrease in the direction from the gate to the isolation region. The purpose of this is to make the pinned voltage decrease in the direction from the gate to the isolation region, thereby increasing the charge transfer efficiency, reducing the lag, and decreasing the remaining charge in the photodiode.

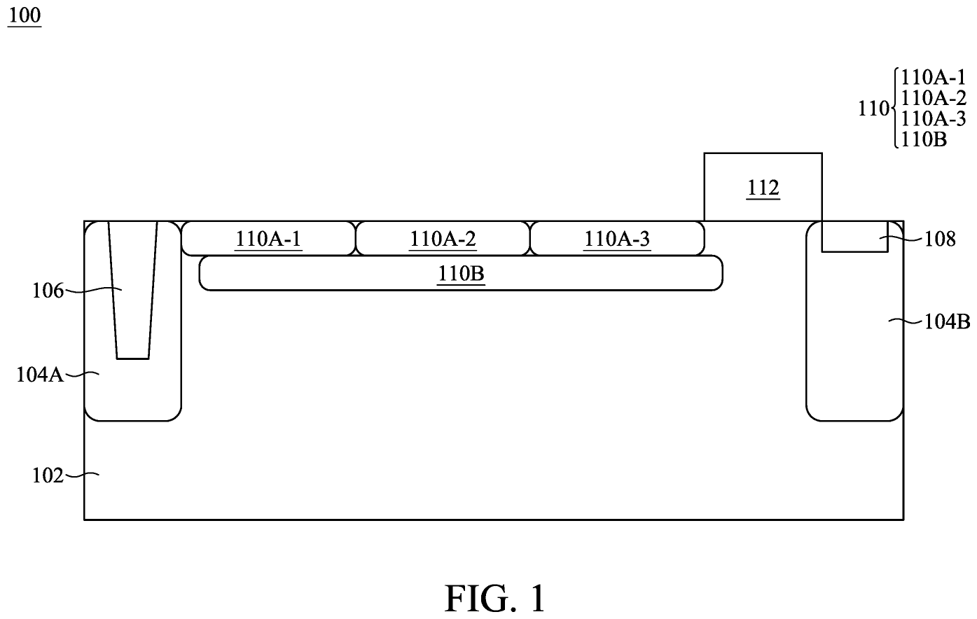

FIG. 1 is a cross-sectional view of an image sensor structure 100 illustrated according to some embodiments of the present invention. Referring to FIG. 1, the image sensor structure 100 includes a substrate 102. The substrate 102 is a bulk semiconductor substrate, such as a semiconductor wafer. For example, the substrate 102 is a silicon wafer. The substrate 102 may include silicon or another elemental semiconductor material, such as germanium. In other embodiments, the substrate 102 includes a compound semiconductor. The compound semiconductor may include gallium arsenide (GaAs), silicon carbide (SiC), indium arsenide (InAs), indium phosphide (InP), gallium phosphide (GaP), another suitable material, or a combination thereof.

In some embodiments, the substrate 102 includes a semiconductor-on-insulator (SOI) substrate. A semiconductor-on-insulator (SOI) substrate can be fabricated using a separation by implantation of oxygen (SIMOX) process, a wafer bonding process, another suitable method or a combination thereof. In some embodiments, the substrate 102 has a first conductive type, such as a P-type.

As shown in FIG. 1, a first well region 104A and a second well region 104B are formed in the substrate 102. The first well region 104A and the second well region 104B are separated from each other. Specifically, the first well region 104A and the second well region 104B can be formed by an implantation process using an implantation mask to selectively implant a dopant into the substrate 102. In some embodiments, the first well region 104A and the second well region 104B have the first conductivity type, such as a P-type. For example, the dopant is a P-type dopant, such as boron or BF₂.

Next, an isolation region 106 is formed in the first well region 104A. Specifically, a photoresist material is formed on the top surface of the first well region 104A by a suitable process, such as spin coating or a chemical vapor deposition (CVD) process, an atomic layer deposition (ALD) process, a physical vapor deposition (PVD) process, a molecular beam deposition (MBD) process, a plasma enhanced chemical vapor deposition (PECVD) process, other suitable methods or a combination thereof. Then, optical exposure, post-exposure baking and development are performed to remove a portion of the photoresist material to form a patterned photoresist. The patterned photoresist layer will serve as an etching mask for etching. A bi- or tri-layered photoresist can be performed. Then, any acceptable etch process, such as reactive ion etching (RIE), neutral beam etching (NBE), the like, or a combination thereof is used to etch through a portion of the first well region 104A to form a trench in the first well region 104A. Next, the patterned photoresist layer can be removed by etching or other suitable methods.

Next, the trench is filled with an insulating material by a suitable deposition process, such as a chemical vapor deposition process, an atomic layer deposition process, a physical vapor deposition process, a molecular beam deposition process, a plasma enhanced chemical vapor deposition process, another suitable deposition process, or a combination thereof to form the isolation region 106. In some embodiments, the insulating material of the isolation region 106 is, for example, silicon oxide, silicon nitride, silicon oxynitride, or the like or a combination thereof. In some embodiments, the isolation region 106 may be a shallow trench isolation (STI) region or a deep trench isolation (DTI) region.

Next, a floating diffusion node 108 is formed in the second well region 104B. Specifically, the floating diffusion node 108 may be formed by an implantation process using an implantation mask to selectively implant a dopant into the second well region 104B. In some embodiments, the floating diffusion node 108 has a second conductivity type that is the opposite of the first conductivity type, such as an N-type. For example, the dopant is an N-type dopant, such as phosphorus or arsenic.

Next, a pinned photodiode 110 is formed in the substrate 102 and between the first well region 104A and the second well region 104B. The pinned photodiode 110 includes a first doped region 110A and a second doped region 110B. The first doped region 110A is formed in the substrate 102, and the second doped region 110B is formed under the first doped region 110A. The first doped region 110A is in direct contact with the first well region 104A. In some embodiments, the first doped region 110A has the first conductivity type, such as a P-type. For example, the dopant is a P-type dopant, such as boron or BF₂. In some embodiments, the second doped region 110B has the second conductivity type, such as an N-type. For example, the dopant is an N-type dopant, such as phosphorus or arsenic.

The first doped region 110A has a first region 110A-1, a second region 110A-2, and a third region 110A-3. Specifically, an implantation mask that exposes the first region 110A-1, the second region 110A-2, and the third region 110A-3 is formed to implant a dopant into the first region 110A-1, the second region 110A-2 and the third region 110A-3. The implant mask is removed. Next, an implantation mask that exposes the first region 110A-1 and the second region 110A-2 is formed to implant a dopant into the first region 110A-1 and the second region 110A-2. The implant mask is removed afterwards. Next, an implantation mask that exposes the first region 110A-1 is formed to implant a dopant into the first region 110A-1. The implant mask is removed afterwards. The first doped region 110A has a first doping concentration. Since the doping concentrations used in the aforementioned implantation processes are substantially the same, the first doping concentration of the first doped region 110A is non-uniform. Specifically, the first doping concentration decreases from the isolation region 106 to a gate 112. In other words, the doping concentration of the first region 110A-1 is greater than the doping concentration of the second region 110A-2. The doping concentration of the second region 110A-2 is greater than the doping concentration of the third region 110A-3. In some embodiments, the doping concentration of the first region 110A-1 is 1E18˜1E21 cm⁻³, such as 6E18˜1.2E19 cm⁻³. The doping concentration of the second region 110A-2 is 6E17˜6E20 cm⁻³, such as 4E18˜8E18 cm⁻³. The doping concentration of the third region 110A-3 is 3E17˜3E20 cm⁻³, such as 2E18˜4E18 cm⁻³.

The doping concentration of the first doped region 110A is greater than that of the second doped region 110B. Specifically, the doping concentration of the first region 110A-3, which has the lowest doping concentration, of the first doped region 110A is greater than that of the second doped region 110B.

Next, the gate 112 is formed on the substrate 102 and between the first well region 104A and the second well region 104B. Specifically, a conductive layer is formed on the substrate 102 using a chemical vapor deposition process, an atomic layer deposition process, a physical vapor deposition process, a molecular beam deposition process, a plasma-enhanced chemical vapor deposition process, another suitable deposition process, or a combination thereof. The material of the conductive layer may be a conductive material, such as amorphous silicon, polycrystalline silicon, metal, metal nitride, conductive metal oxide, or the like or a combination thereof. For example, the material of the conductive layer may include tungsten (W), copper, tungsten nitride, ruthenium, silver, gold, rhodium, molybdenum, nickel, cobalt, cadmium, zinc, an alloy thereof, a combination thereof or the like.

Next, a patterning process is performed. a photoresist material is formed on the top surface of the conductive layer by a suitable process, such as spin coating or a chemical vapor deposition process, an atomic layer deposition process, a physical vapor deposition process, a molecular beam deposition process, a plasma enhanced chemical vapor deposition process, other suitable methods or a combination thereof. Then, optical exposure, post-exposure baking and development are performed to remove a portion of the photoresist material to form a patterned photoresist. The patterned photoresist layer will serve as an etching mask for etching. A bi- or tri-layered photoresist can be performed. Then, any acceptable etch process, such as reactive ion etching (RIE), neutral beam etching (NBE), the like, or a combination thereof is used to etch the conductive layer to form the gate 112 on the substrate 102 and between the first well region 104A and the second well region 104B. Next, the patterned photoresist layer can be removed by etching or other suitable methods.

In this embodiment, the charge transfer efficiency can be increased to reduce the lag time by making the first doped region of the pinned photodiode have a non-uniform doping concentration, for example, the doping concentration decreasing from the isolation region to the gate. Furthermore, an additional full well capacity can be produced.

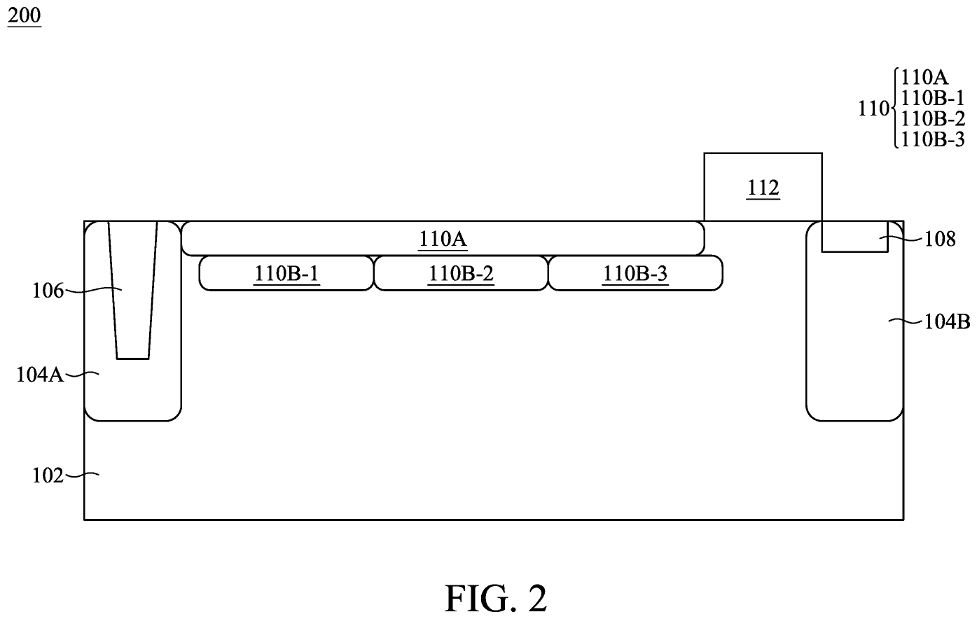

FIG. 2 is a cross-sectional view of an image sensor structure 200 illustrated according to some embodiments of the present invention. It should be noted that the same or similar elements or layers corresponding to those of the image sensor structure 100 are denoted by similar reference numerals. In some embodiments, the same or similar elements or layers denoted by similar reference numerals have the same meanings, which will not be repeated for the sake of brevity.

The difference between the image sensor structure 200 and the image sensor structure 100 is that the first doped region 110A does not have a non-uniform doping concentration; and the second doped region 110B has a non-uniform doping concentration. The second doped region 110B has a first region 110B-1, a second region 110B-2, and a third region 110B-3. The second doping concentration of the second doped region 110B is non-uniform. Specifically, the second doping concentration decreases in a direction from the gate 112 to the isolation region 106. In other words, the doping concentration of the first region 110B-1 is smaller than that of the second region 110B-2. The doping concentration of the second region 110B-2 is smaller than that of the third region 110B-3. In some embodiments, the doping concentration of the first region 110B-1 of the second doped region 110B is 1E16˜1E19 cm⁻³, such as 1E17˜4E17 cm⁻³. The doping concentration of the second region 110B-2 is 1E16˜1E19 cm⁻³, such as 2E17˜7E17 cm⁻³. The doping concentration of the third region 110B-3 is 1E16˜1E19 cm⁻³, such as 3E17˜1E18 cm⁻³.

The doping concentration of the first doped region 110A is greater than that of the second doped region 110B. Specifically, the doping concentration of the first doped region 110A is greater than that of the third region 110B-3, which has the highest doping concentration, of the second doped region 110B.

In this embodiment, the charge transfer efficiency can also be increased to reduce the lag time and the charge remaining in the photodiode can be reduced by making the second doped region of the pinned photodiode have a non-uniform doping concentration, for example, the doping concentration decreasing from the gate to the isolation region. Furthermore, an additional full well capacity can be produced.

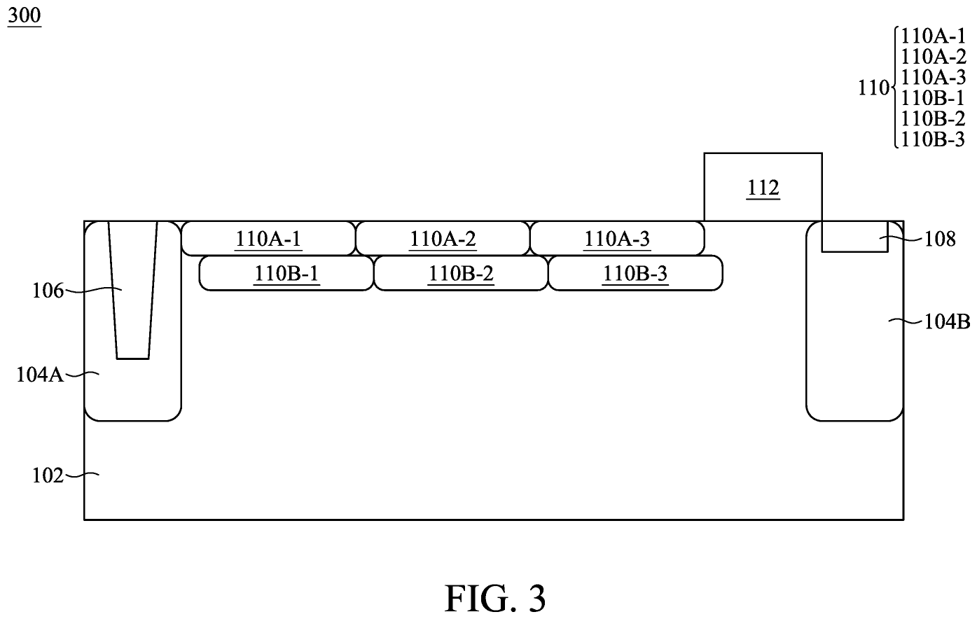

FIG. 3 is a cross-sectional view of an image sensor structure 300 illustrated according to some embodiments of the present invention. It should be noted that the same or similar elements or layers corresponding to those of the image sensor structure 100 are denoted by similar reference numerals. In some embodiments, the same or similar elements or layers denoted by similar reference numerals have the same meanings, which will not be repeated for the sake of brevity.

The difference between the image sensor structure 300 and the image sensor structure 100 is that the second doped region 110B also has a non-uniform doping concentration. The second doped region 110B has a first region 110B-1, a second region 110B-2, and a third region 110B-3. The second doping concentration of the second doped region 110B is non-uniform. Specifically, the second doping concentration decreases in a direction from the gate 112 to the isolation region 106. In other words, the doping concentration of the first region 110B-1 is smaller than that of the second region 110B-2. The doping concentration of the second region 110B-2 is smaller than that of the third region 110B-3. In some embodiments, the doping concentration of the first region 110B-1 of the second doped region 110B is 1E16˜1E19 cm⁻³, such as 1E17˜4E17 cm⁻³. The doping concentration of the second region 110B-2 is 1E16˜1E19 cm⁻³, such as 2E17˜7E17 cm⁻³. The doping concentration of the third region 110B-3 is 1E16˜1E19 cm⁻³, such as 3E17˜1E18 cm⁻³. In some embodiments, the doping concentration of the first region 110A-1 of the first doped region 110A is 1E18˜1E21 cm⁻³, such as 6E18˜1.2E19 cm⁻³. The doping concentration of the second region 110A-2 is 6E17˜6E20 cm ³, such as 4E18˜8E18 cm⁻³. The doping concentration of the third region 110A-3 is 3E17˜3E20 cm⁻³, such as 2E18˜4E18 cm⁻³.

The doping concentration of the first doped region 110A is greater than that of the second doped region 110B. Specifically, the doping concentration of the third region 110A-3, which has the lowest doping concentration, of the first doped region 110A is greater than that of the third region 110B-3, which has the highest doping concentration of the second doped region 110B.

In this embodiment, the charge transfer efficiency can be increased to reduce the lag time and the charge remaining in the photodiode can be reduced by making one or both of the first doped region and the second doped region of the pinned photodiode have a non-uniform doping concentration, for example, the doping concentration of the first doped region decreasing from the isolation region to the gate, or the doping concentration of the second doped region decreasing from the gate to the isolation region. Furthermore, an additional full well capacity can be produced.

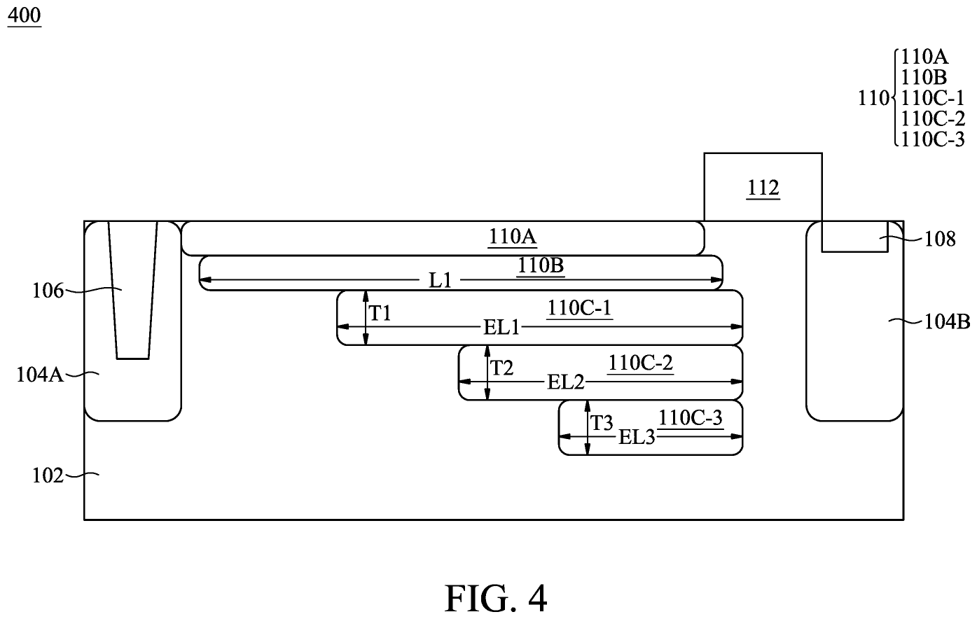

FIG. 4 is a cross-sectional view of an image sensor structure 400 illustrated according to some embodiments of the present invention. It should be noted that the same or similar elements or layers corresponding to those of the image sensor structure 100 are denoted by similar reference numerals. In some embodiments, the same or similar elements or layers denoted by similar reference numerals have the same meanings, which will not be repeated for the sake of brevity.

The difference between the image sensor structure 400 and the image sensor structure 100 is that the pinned photodiode 110 further includes a first deep doped region 110C-1, a second deep doped region 110C-2 and a third deep doped region 110C-3 that are disposed under the second doped region 110B. Specifically, the first deep doped region 110C-1 is formed under the second doped region 110B, the second deep doped region 110C-2 is formed under the first deep doped region 110C-1, and the third deep doped region 110C-3 is formed under the doped region 110C-2. In some embodiments, the first deep doped region 110C-1, the second deep doped region 110C-2 and the third deep doped region 110C-3 have the second conductivity type, such as an N-type. For example, the dopant is an N-type dopant, such as phosphorus or arsenic.

In some embodiments, the first deep doped region 110C-1, the second deep doped region 110C-2 and the third deep doped region 110C-3 have a third doping concentration, a fourth doping concentration and a fifth doping concentration, respectively, and the second doping concentration is greater than the third doping concentration, the third doping concentration is greater than or equal to the fourth doping concentration, and the fourth doping concentration is greater than or equal to the fifth doping concentration.

As shown in FIG. 4, the second doped region 110B, the first deep doped region 110C-1, the second deep doped region 110C-2 and the third deep doped region 110C-3 extend from the gate 112 to the isolation region 106. The total thickness of the second doped region 110B, the first deep doped region 110C-1, the second deep doped region 110C-2, and the third deep doped region 110C-3 decreases in a direction from the gate 112 to the isolation region 106. In other words, the second doped region 110B, the first deep doped region 110C-1, the second deep doped region 110C-2 and the third deep doped region 110C-3 have a first length L1, a first extension length EL1, a second extension length EL2 and a third extension length EL3, respectively. The first length L1 is greater than the first extension length EL1, the first extension length EL1 is greater than the second extension length EL2, and the second extension length EL2 is greater than the third extension length EL3. The length described herein refers to the vertical distance between a left sidewall and a right sidewall of a doped region or an element.

The second doped region 110B, the first deep doped region 110C-1, the second deep doped region 110C-2 and the third deep doped region 110C-3 have a left sidewall and a right sidewall that is closer to the second well region 104B, respectively. The right sidewalls of the first deep doped region 110C-1, the second deep doped region 110C-2 and the third deep doped region 110C-3 are closer to the second well region 104B than the right sidewall of the second doped region 110B. Therefore, the charge transfer efficiency can be increased to reduce the lag time and the charge remaining in the photodiode can be reduced. The image sensor structures 100, 200 and 300 only establish a gradient potential profile in a horizontal direction while the image sensor structure 400 has an additional gradient potential profile in a vertical direction, so it can achieve a better charge transfer efficiency.

The projections of the right sidewalls of the second doped region 110B, the first deep doped region 110C-1, the second deep doped region 110C-2 and the third deep doped region 110C-3 on the bottom surface of the substrate 102 overlap the projection of the gate 112 on the bottom surface of the substrate 102 to ensure that when the charge of the photodiode is fully loaded, the excessive charge which is not collected by the photodiode will not overflow to the drain.

The thickness described herein refers to the vertical distance from a top surface to a bottom surface of a doped region or an element. The first deep doped region 110C-1, the second deep doped region 110C-2 and the third deep doped region 110C-3 have a first thickness T1, a second thickness T2 and a third thickness T3, respectively. The first thickness T1 is 0.1 μm˜2 μm, such as 0.2 μm˜0.5 μm. The second thickness T2 is 0.1 μm˜2 μm, such as 0.2 μm˜0.5 μm. The third thickness T3 is 0.1 μm˜2 μm, such as 0.2 μm˜0.5 μm.

The charge transfer efficiency be increased to reduce the lag time and the charge remaining in the photodiode can be reduced by disposing a plurality of deep doped regions under the second doped region of the pinned photodiode and the total thickness decreases from the gate to the isolation region, which is equivalent to the doping concentration of the second doped region of the pinned photodiode decreasing in a direction from the gate to the isolation region.

In addition, since a plurality of deep doped regions are disposed under the second doped region and the total thickness decreases from the gate to the isolation region, if the photons are excited in a deeper layer of the substrate, it will be easier for the photodiode to collect the photons.

Although this embodiment illustrates three deep doped regions, the number of the deep doped regions is not limited thereto. The number of deep doped regions may also be, for example, one, two, or four depending on design requirements. In addition, it can be understood by one of ordinary skill in the art that each embodiment can be combined depending on actual needs.

Compared with the prior art, the image sensor structures provided by the embodiments of the present invention have one or more of the following advantages:

(1) The charge transfer efficiency can be increased to reduce the lag time by making one or both of the first doped region and the second doped region of the pinned photodiode have a non-uniform doping concentration, for example, the doping concentration of the first doped region decreasing from the isolation region to the gate, or the doping concentration of the second doped region decreasing from the gate to the isolation region.

(2) In addition, since a plurality of deep doped regions are disposed under the second doped region and the total thickness decreases from the gate to the isolation region, if the photons are excited in a deeper layer of the substrate, it will be easier for the photodiode to collect the photons.

(3) Furthermore, in addition to producing a gradient potential profile in a horizontal direction, a plurality of deep doped regions can further produce an additional gradient potential profile in a vertical direction, so it can achieve a better charge transfer efficiency.

Although the embodiments of the present disclosure and the advantages have been disclosed above, it should be understood that one of ordinary skill in the art can make changes, substitutions, and modification without departing from the spirit and scope of the present disclosure. In addition, the scope of the present disclosure is not limited to the process, machine, manufacture, compositions of matter, devices, methods and steps of particular embodiments described in the specification. Any one of ordinary skill in the art will readily appreciate from the disclosure of the present disclosure, processes, machines, manufacture, compositions of matter, devices, methods, or operations presently existing or later to be developed. As long as they can perform substantially the same functions or achieve substantially the same results in the embodiments described herein, they may be used according to the present disclosure Accordingly, the scope of the present disclosure includes such processes, machines, manufacture, compositions of matter, devices, methods, or steps. In addition, each claim constitutes an individual embodiment, and the scope of the present disclosure also includes a combination of the claims and the embodiments. The features of the various embodiments can be arbitrarily mixed and used as long as they do not contradict or conflict the spirit of the invention.

1. An image sensor structure, comprising:
a substrate having a first conductive type;
a first well region and a second well region disposed in the substrate and separated from each other;
an isolation region disposed in the first well region;
a gate disposed on the substrate and between the first well region and the second well region; and
a pinned photodiode disposed in the substrate and between the first well region and the second well region, wherein the pinned photodiode comprises:
a first doped region disposed in the substrate and having a first doping concentration and the first conductive type; and
a second doped region disposed under the first doped region and having a second doping concentration and a second conductive type that is
the opposite of the first conductive type, wherein one or both of the first doping concentration and the second doping concentration is non-uniform, and the first doping concentration is greater than the second doping concentration.

2. The image sensor structure as claimed in claim 1, wherein the first doping concentration decreases in a direction from the isolation region to the gate.

3. The image sensor structure as claimed in claim 1, wherein the second doping concentration decreases in a direction from the gate to the isolation region.

4. The image sensor structure as claimed in claim 1, wherein the pinned photodiode further comprises:
a first deep doped region having the second conductive type and disposed under the second doped region;
a second deep doped region having the second conductive type and disposed under the first deep doped region; and
a third deep doped region having the second conductive type and disposed under the second deep doped region, wherein the first deep doped region, the second deep doped region, and the third deep doped region extend toward the first well region.

5. The image sensor structure as claimed in claim 4, wherein the first doped region, the first deep doped region, the second deep doped region, and the third deep doped region have a first length, a first extension length, a second extension length, and a third extension length, respectively, and the first length is greater than the first extension length, the first extension length is greater than the second extension length, and the second extension length is greater than the third extension length.

6. The image sensor structure as claimed in claim 4, wherein the first deep doped region, the second deep doped region, and the third deep doped region have a third doping concentration, a fourth doping concentration and a fifth doping concentration, respectively, and the second doping concentration is greater than the third doping concentration, the third doping concentration is greater than or equal to the fourth doping concentration, and the fourth doping concentration is greater than or equal to the fifth doping concentration.

7. The image sensor structure as claimed in claim 4, wherein projections of right sidewalls of the second doped region, the first deep doped region, the second deep doped region and the third deep doped region on a bottom surface of the substrate overlap a projection of the gate on the bottom surface of the substrate.

8. The image sensor structure as claimed in claim 1, wherein the first doped region is in direct contact with the first well region.

9. The image sensor structure as claimed in claim 1, further comprising a floating diffusion node disposed in the second well region.

10. The image sensor structure as claimed in claim 9, wherein the floating diffusion node has the second conductive type.

11. A method of forming an image sensor structure, comprising:
providing a substrate having a first conductive type;
forming a first well region and a second well region in the substrate, wherein the first well region and the second well region are separated from each other;
forming an isolation region in the first well region;
forming a gate on the substrate and between the first well region and the second well region; and
forming a pinned photodiode in the substrate and between the first well region and the second well region, wherein the pinned photodiode comprises:
forming a first doped region in the substrate, wherein the first doped region has a first doping concentration and the first conductive type; and
forming a second doped region under the first doped region, wherein the second doped region has a second doping concentration and a second conductive type that is the opposite of the first conductive type, wherein one or both of the first doping concentration and the second doping concentration is non-uniform, and the first doping concentration is greater than the second doping concentration.

12. The method as claimed in claim 11, wherein the first doping concentration decreases in a direction from the isolation region to the gate.

13. The method as claimed in claim 11, wherein the second doping concentration decreases in a direction from the gate to the isolation region.

14. The method as claimed in claim 11, wherein the pinned photodiode further comprises:
forming a first deep doped region under the second doped region, wherein the first deep doped region has the second conductive type;
forming a second deep doped region under the first deep doped region, wherein the second deep doped region has the second conductive type; and
forming a third deep doped region under the second deep doped region, wherein the third deep doped region has the second conductive type, and the first deep doped region, the second deep doped region and the third deep doped region extend toward the first well region.

15. The method as claimed in claim 14, wherein the first doped region, the first deep doped region, the second deep doped region, and the third deep doped region have a first length, a first extension length, a second extension length, and a third extension length, respectively, and the first length is greater than the first extension length, the first extension length is greater than the second extension length, and the second extension length is greater than the third extension length.

16. The method as claimed in claim 14, wherein the first deep doped region, the second deep doped region and the third deep doped region have a third doping concentration, a fourth doping concentration, and a fifth doping concentration, respectively, and the second doping concentration is greater than the third doping concentration, the third doping concentration is greater than or equal to the fourth doping concentration, and the fourth doping concentration is greater than or equal to the fifth doping concentration.

17. The method as claimed in claim 14, wherein projections of right sidewalls of the second doped region, the first deep doped region, the second deep doped region and the third deep doped region on a bottom surface of the substrate overlap projection of the gate on the bottom surface of the substrate.

18. The method as claimed in claim 11, wherein the first doped region is in direct contact with the first well region.

19. The method as claimed in claim 11, further comprising a floating diffusion node disposed in the second well region.

20. The method as claimed in claim 19, wherein the floating diffusion node has the second conductive type.
